(19) United States
(12) Patent Application Publication
(10) Pub. No.: US 2025/0072183 A1
(43) Pub. Date: Feb. 27, 2025

(54) EYE-TRACKING APPARATUS INCLUDING TRANSPARENT METAL MESH TRACES FOR MICRO LIGHT EMITTING DIODES

(71) Applicant: Meta Platforms Technologies, LLC, Menlo Park, CA (US)

(72) Inventors: Yasuo Morimoto, Cupertino, CA (US); Jiang Zhu, Cupertino, CA (US); Francis Lawrence Leard, Sadbury, MA (US); Kuan Pei Yap, San Jose, CA (US)

(21) Appl. No.: 18/454,504

(22) Filed: Aug. 23, 2023

(51) Int. Cl. H01L 33/62; G02B 27/01; H01L 25/075

(52) U.S. Cl. CPC H01L 33/62; G02B 27/0179; H01L 25/0753; G02B 2027/0187

(57) ABSTRACT

The disclosed apparatus may include an eye-tracking system incorporating transparent metal mesh. For example, a head-mounted display device may include optical lenses with eye-tracking layers. In one or more examples, the eye-tracking layers may include micro light emitting diodes connected to an LED controller with transparent metal mesh traces. Moreover, the eye-tracking layers may further include one or more wireless metal mesh antennas. As such, due to the transparency of metal mesh over previous components, the disclosed eye-tracking system can feature improved functionality and visibility when incorporated into a head-mounted display device. Various other implementations also disclosed.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 illustrates an example head-mounted display device that includes one or more light emitting diodes and their traces in accordance with one or more implementations.

FIG. 2 illustrates an example eye-tracking system in accordance with one or more implementations.

FIG. 3 illustrates a side view of an example lens stack for use in connection with an eye-tracking system in accordance with one or more implementations.

FIG. 4 illustrates a side view of an example lens stack fitted into a glasses frame relative to a human eye in accordance with one or more implementations.

FIG. 5 illustrates an existing eye-tracking layer of a lens stack including resin fiber traces connected to one or more light emitting diodes in accordance with one or more implementations.

FIG. 6 illustrates a front view of a transparent conductor film of a lens stack positioned with one or more micro light emitting diodes and one or more traces made of transparent metal mesh in accordance with one or more implementations.

FIG. 7 illustrates front and side views of a portion of transparent metal mesh in accordance with one or more implementations.

FIG. 8 illustrates a side view of a transparent conductor film of a lens stack fitted into a glasses frame in accordance with one or more implementations.

FIG. 9 illustrates an example wireless metal mesh antenna in accordance with one or more implementations.

FIG. 10 illustrates front and side views of a transparent conductor film of a lens stack with micro light emitting diodes and the associated transparent metal mesh traces as well as with one or more wireless metal mesh antennas in accordance with one or more implementations.

FIG. 11 illustrates a front view of a transparent conductor film of a lens stack with micro light emitting diodes and the associated transparent metal mesh traces as well as with one or more wireless metal mesh antennas in accordance with one or more implementations.

FIG. 12 illustrates front and side views of a transparent conductor film of a lens stack with micro light emitting diodes and the associated transparent metal mesh traces on a first side of the transparent conductor film and one or more wireless metal mesh antennas on a second side of the transparent conductor film in accordance with one or more implementations.

FIG. 13 illustrates perspective views of an augmented-reality system in accordance with one or more implementations.

FIG. 14 illustrates a perspective view of a virtual-reality system in accordance with one or more implementations.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION OF EXEMPLARY IMPLEMENTATIONS

Current eye-tracking techniques are often incorporated into different types of head-mounted display devices. For example, these techniques typically include physical components that observe a viewer's eye movement to determine what the viewer is looking at within a display. In some implementations, these components can include one or more lights that shine onto the viewer's eyes and one or more cameras that observe how the one or more lights are reflected by the viewer's eyes.

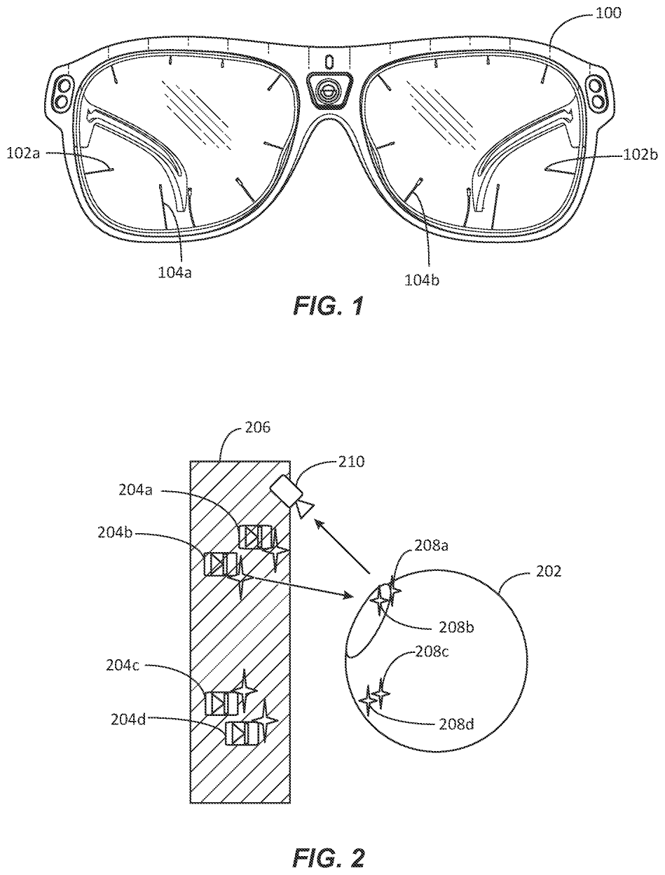

As head-mounted display devices become smaller and more sophisticated, the physical components of typical eye-tracking systems can be problematic. For example, as shown in FIG. 1, an eye-tracking system may be incorporated into a pair of augmented reality glasses 100. In one or more implementations, the eye-tracking system may include multiple light emitting diodes (LEDs), such as LEDs 102a and 102b, that are positioned on the augmented reality glasses 100 in areas where they can shine light onto a viewer's eyes. In additional implementations, the eye-tracking system can further utilize light outside of the visible spectrum. For example, in some implementations, the eye-tracking system may utilize infrared or ultraviolet light and corresponding camera detection.

As further shown in FIG. 1, each of the LEDs positioned on the augmented reality glasses 100 can also include a trace, such as the traces 104a and 104b. In one or more implementations, the traces excite the LEDs (e.g., allow power to flow to and away from the LEDs) so that the LEDs can produce light. Despite this, most eye-tracking systems use resin fiber traces. As such, and as shown in FIG. 1, such traces are easily seen by the viewer when they are positioned on lenses of the augmented reality glasses 100, which can be distracting to a view and may even block displayed content.

As such, the present disclosure describes an eye-tracking apparatus that utilizes transparent metal mesh traces to power LEDs. In one or more implementations, the disclosed apparatus utilizes transparent metal mesh traces that include an aperture ratio and metal mesh density that can make the traces effectively invisible to the human eye. Additionally, the disclosed apparatus can further optimize lens space by incorporating wireless metal mesh antennas in connection with the same lens layer as the metal mesh traces and LEDs.

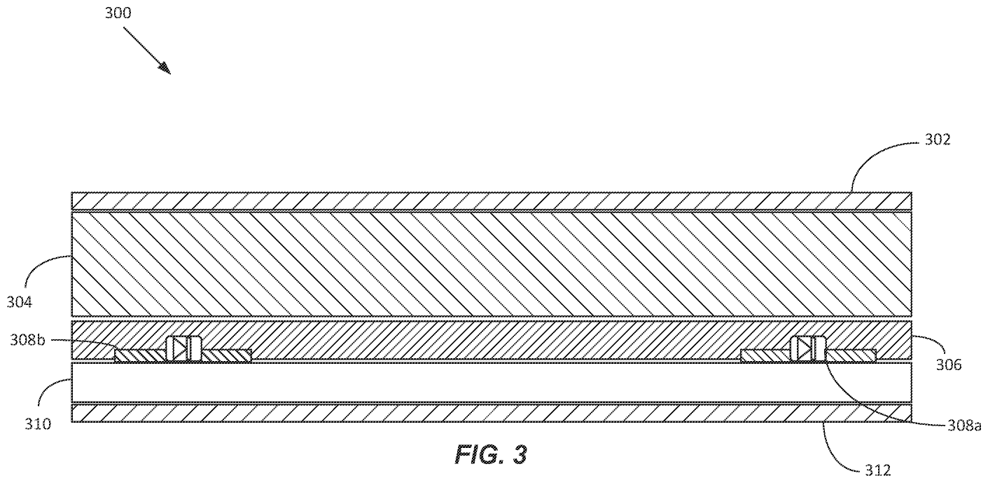

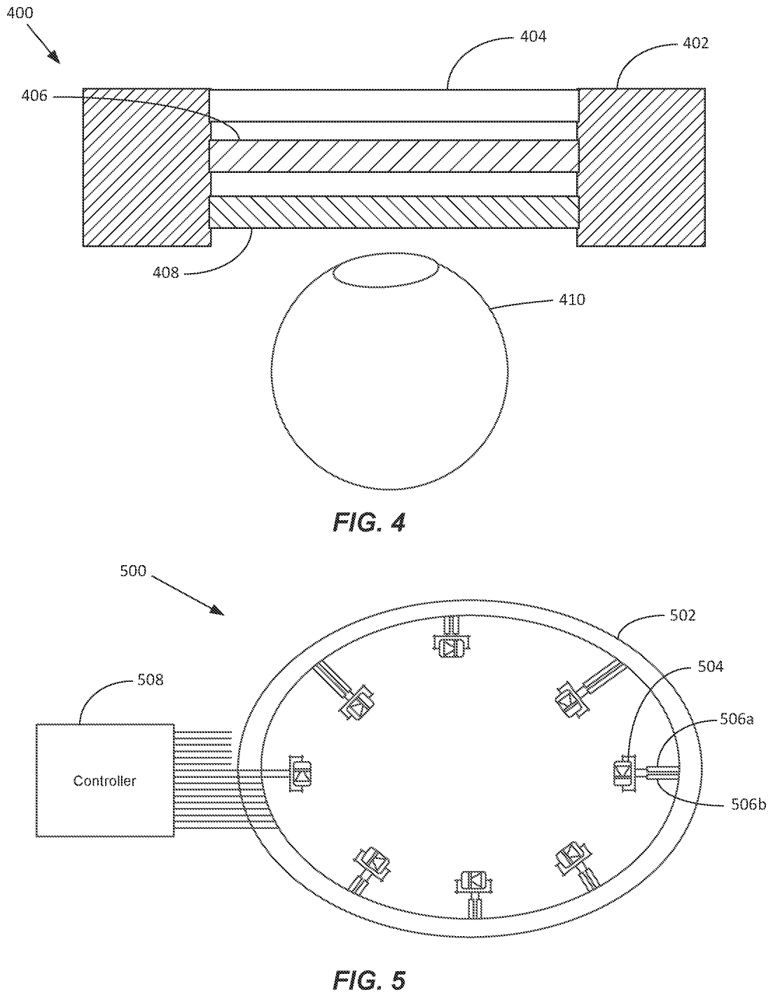

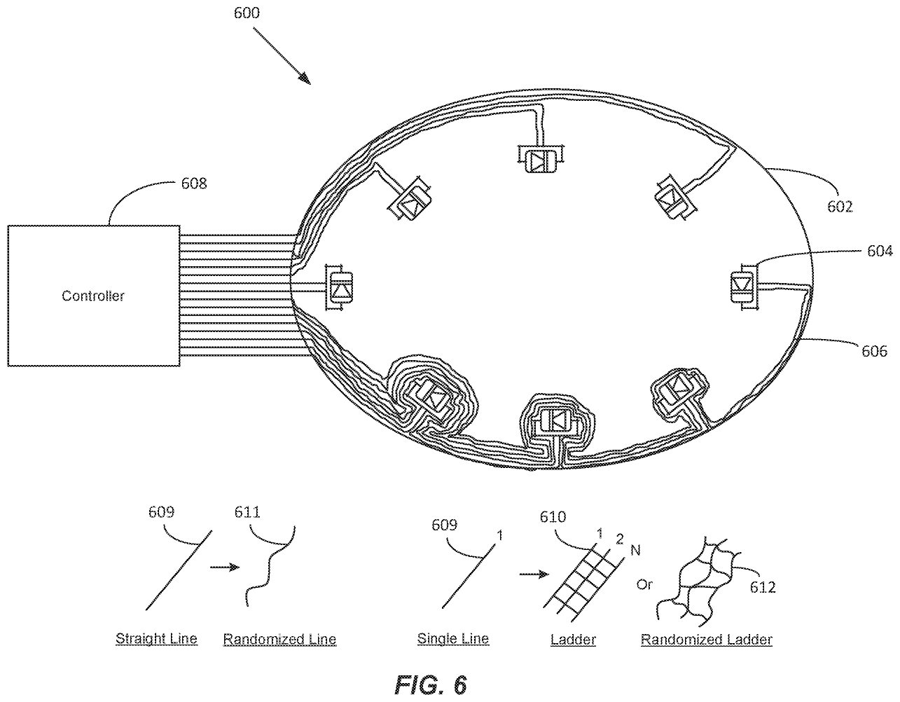

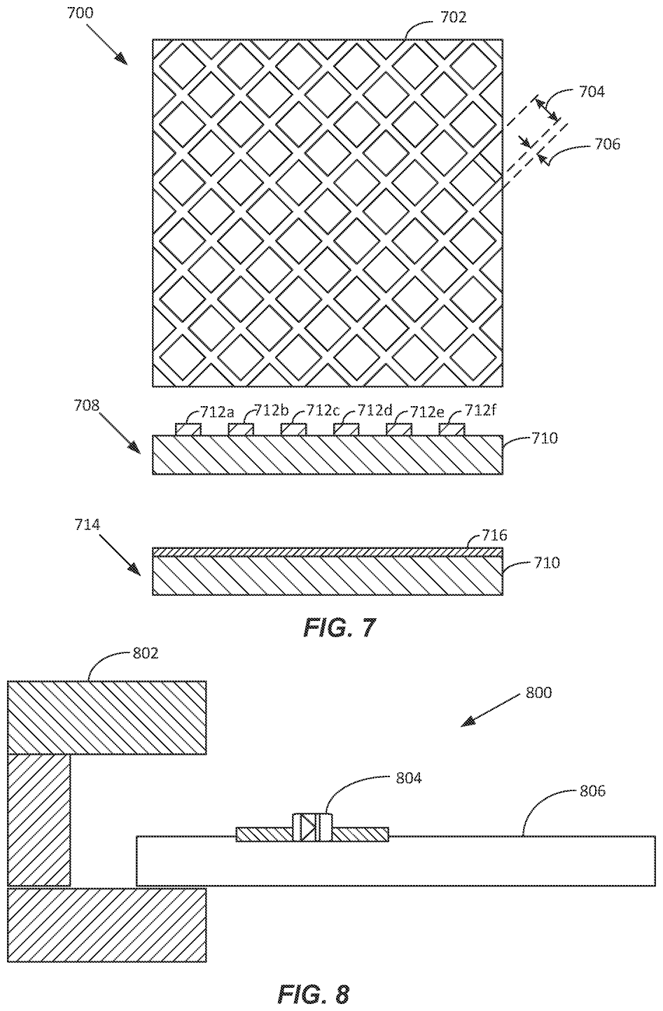

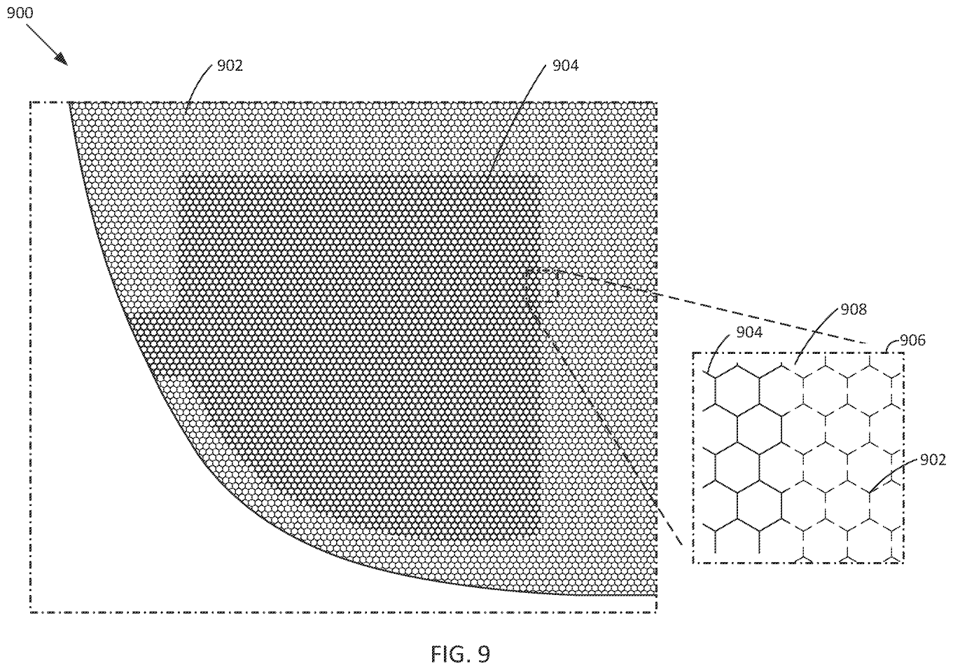

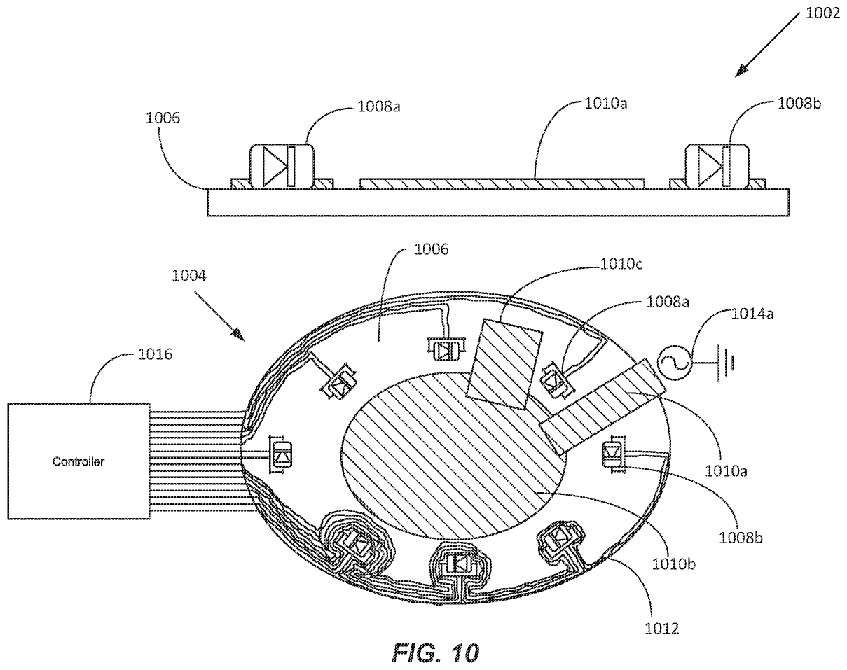

The following will provide, with reference to the remaining FIGS. 2-12, detailed descriptions of eye-tracking systems that incorporate transparent metal mesh. For example, FIG. 2 demonstrates how an eye-tracking system can use reflected light to track a viewer's eye movement. FIG. 3 illustrates an example lens stack of multiple layers including an eye-tracking layer with one or more micro LEDs. FIG. 4 illustrates another example lens stack relative to a human eye, while FIG. 5 illustrates an existing eye-tracking layer including resin fiber traces. FIG. 6 illustrates an eye-tracking layer including micro LEDs connected to a controller by transparent metal mesh traces. FIG. 7 illustrates additional detail with regard to transparent metal mesh and FIG. 8 illustrates an eye-tracking layer relative to a glasses frame. FIG. 9 illustrates additional detail with regard to wireless metal mesh antennas. FIGS. 10-12 illustrate example implementations of an eye-tracking layer of an eye-tracking system including both micro LEDs with transparent metal mesh traces and wireless metal mesh antennas.

As just mentioned, eye-tracking systems often rely on observing how a viewer's eye reflects light to determine how the eye is moving. For example, as shown in FIG. 2, a human eye 202 may view virtual content displayed via a lens 206 within a head-mounted display device (e.g., such as the augmented reality glasses 100 shown in FIG. 1). An eye-tracking system may include LEDs 204a, 204b, 204c, and 204d that are positioned on one or more layers of the lens 206 such that they shine light onto the human eye 202. Due to the common physiology of the human eye 202, the eye-tracking system can rely on glints 208a, 208b, 208c, 208d (e.g., corneal reflections) to determine how the human eye 202 is moving and/or rotating. For example, the eye-tracking system can rely on images of the glints 208a-208d captured by a camera 210 to determine a position of the pupil of the human eye 202 relative to any/all of the glints 208a-208d. From this information, the eye-tracking system can determine a position of the human eye 202 relative to virtual content displayed on one or more additional layers of the lens 206.

In one or more implementations, as shown in FIG. 3, physical components of an eye-tracking system may be embedded into one or more layers of a lens stack 300 of a head-mounted display device. For example, the lens stack 300 can include a first hard coat/anti-reflection layer 302, a lens layer 304, an optical clear adhesive 306, an eye-tracking layer 310 including transparent conductor film, and a second hard coat/anti-reflection layer 312. In one or more implementations, one or more micro LEDs 308a, 308b and associated traces may be positioned on the transparent conductor film of the eye-tracking layer 310. In at least one implementation, the layers of the lens stack 300 may share a common shape such that the lens stack 300 can serve as a transparent optical aperture of a head-mounted display device (HMD).

In at least one implementation, as shown in FIG. 4, a lens stack 400 can include a world-side lens 404, a waveguide 406 (e.g., a display), and an eye-tracking layer 408. For example, each of the world-side lens 404, the waveguide 406, and the eye-tracking layer 408 may be fitted into a frame 402, such as an eyeglasses frame. The world-side lens 404 may include an optic feature such as a dimming feature. Moreover, the eye-tracking layer 408 may include one or more micro LEDs and/or cameras, as described above. In this implementation, the eye-tracking layer 408 may be positioned within the lens stack 400 such that it is closest to a viewer's eye 410 when the viewer has positioned the frame 402 on their face.

As mentioned above, typical eye-tracking systems include LEDs connected to a controller with resin fiber. As shown in FIG. 5, an eye-tracking system 500 can include LEDs (such as an LED 504) that are positioned on an eye-tracking layer 502 and connected to a controller 508 by resin fiber traces (such as resin fiber traces 506a, 506b). In one or more implementations, the resin fiber traces included in the eye-tracking system 500 are wide and/or thick enough that they are visible to a viewer. As such, the resin fiber traces may interfere with the viewer's ability to see displayed content when the eye-tracking system 500 is incorporated into a head-mounted display device.

In one or more implementations, the disclosed apparatus replaces these typically-used resin fiber traces with transparent metal mesh traces. For example, as shown in FIG. 6, an eye-tracking apparatus 600 can include one or more micro LEDs—such as the micro LED 604—positioned on a transparent conductor film 602. As further shown, the eye-tracking apparatus 600 can include transparent metal mesh traces—such as the transparent metal mesh traces 606—that connect the one or more micro LEDs to an LED controller 608. In one or more implementations, the micro LEDs can be positioned along a periphery of the transparent conductor film 602 (e.g., of the eye-tracking layer), which can correspond to a periphery of a lens layer of a head-mounted display.

In some implementations, one or more of the transparent metal mesh traces can be structured in a single line configuration 609 of transparent metal mesh. In at least one implementation, however, the single line configuration 609 may cause interference with display performance in another layer of the lens stack. As such, the transparent metal mesh may instead be structured in a randomized line configuration 611 to avoid this interference.

As further shown in FIG. 6, the metal mesh traces can be structured in a ladder configuration 610. In the straight ladder configuration 610, a metal mesh trace can include 1 to N transparent metal mesh lines connected by perpendicular metal mesh cross-pieces. In some implementations, a transparent metal mesh trace in the straight ladder configuration 610 can also interfere with other layers of a lens stack (e.g., such as the lens stack 300 shown in FIG. 3 or the lens stack 400 shown in FIG. 4). For example, the straight ladder configuration 610 can cause unwanted visual artifacts in the waveguide 406 shown in FIG. 4. To avoid interference between the eye-tracking layer 408 of the lens stack 400 and the waveguide 406 of the lens stack 400, for example, the transparent metal mesh trace can be structured in a randomized ladder configuration 612, as shown in FIG. 6.

FIG. 7 illustrates additional detail with regard to transparent metal mesh used in the transparent metal mesh traces (e.g., such as the metal mesh traces 606 shown in FIG. 6). For example, a transparent metal mesh 700 can include fine metal lines, filaments, or wires in a grid layout 702. In one or more implementations, the grid layout 702 can include a mesh pitch 704 (MP) that defines a size of the apertures created by the grid layout 702. The grid layout 702 can further include a mesh width 706 (MW). For example, the transparent metal mesh 700 can include a mesh width 706 of less than five micrometers (e.g., 5 μm) as well as a mesh thickness of less than five micrometers (e.g., 5 μm)—as metal mesh with these dimensions are difficult for the human eye to see. In at least one implementation, the grid layout 702 can be defined by:

$$Aperture Ratio = {( ( MP - MW ) / ( MP ) )}^{2}$$

While the implementation shown in FIG. 7 includes the transparent metal mesh 700 in the grid layout 702, other mesh grid geometries are possible. For example, additional implementations may include metal mesh with arbitrary grid geometries. To illustrate, additional grid geometries may include square, rectangular, diamond, hexagonal, or multiple shapes. Moreover, the grid geometry may include aperiodic structures or randomly deformed geometries from periodic structures. Additionally, the grid geometries may change from place to place. For example, the shape is such that the density of the transparent metal mesh can gradually change from place to place.

In some implementations, the transparent metal mesh 700 can also include a mesh density that defines how much metal is in an area of the transparent metal mesh. For example, the mesh density of the transparent metal mesh 700 may adversely affect transparency. As such, in one or more implementations, the transparent metal mesh 700 may include gradient changes in mesh density. For example, in at least one implementation, the transparent metal mesh 700 can include a central area that is less dense than the outer areas—or vice versa. In one or more implementations, this mesh density gradient may improve the transparency of the transparent metal mesh 700 and make virtual content displayed in other layers of the lens stack easier to see.

As further shown in FIG. 7, a side view 708 of the transparent metal mesh 700 can illustrate fine metal lines 712a, 712b, 712c, 712d, 712e, and 712f. As shown in the side view 708, the fine metal lines 712a-712e can have the same mesh width (e.g., the mesh width 706) with a uniform mesh density. In additional implementations, the fine metal lines 712a-712e may have different mesh widths or a gradient mesh density. As further shown in the side view 708, the fine metal lines 712a-712e can be positioned such that they abut a transparent conductor film 710 (e.g., in the eye-tracking layer 310 of the lens stack 300 as shown in FIG. 3). In one or more implementations, the fine metal lines 712a-712e may be secured to the transparent conductor film 710 by an adhesive or other similar means.

In contrast, FIG. 7 further illustrates a side view 714 of an indium tin oxide layer 716 (ITO) deposited on transparent conductor film 710. For example, typical eye-tracking systems may utilize an ITO layer 716, such as shown in the side view 714, rather than a fine metal mesh such as in the transparent metal mesh 700. As discussed above, such an ITO layer 716 may be visible to a human eye when used as micro LED traces in an eye-tracking system thereby potentially blocking displayed virtual content and/or causing viewer distraction.

In one or more implementations, while metal mesh may be used in micro LED traces as described above, it can also be used in other head-mounted display device components. For example, as shown in FIG. 8, a side view 800 shows an eye-tracking layer 806 (e.g., a transparent conductor film) with a micro LED 804 positioned thereon. When the eye-tracking layer 806 is fitted into a frame 802 (e.g., a glasses frame), there may be space on the eye-tracking layer 806 that is not blocked by the frame 802 and/or the micro LED 804. Accordingly, at least one implementation of the head-mounted display device described herein can include one or more wireless metal mesh antennas positioned on the eye-tracking layer 806 adjacent to the one or more micro LEDs utilized by an eye-tracking system.

To illustrate, FIG. 9 illustrates an enlarged view 900 of a wireless metal mesh antenna 904. In one or more implementations, the shape of the wireless metal mesh antenna 904 is defined by a cutout in surrounding metal mesh dummy fill 902 In one or more implementations, as shown by the view 906, the shape of the wireless metal mesh antenna 904 may be facilitated by a boundary 908 between the wireless metal mesh antenna 904 and the metal mesh dummy fill 902. In at least one implementation, the metal mesh dummy fill 902 includes a disconnected mesh structure.

In one or more implementations, the shape of the wireless metal mesh antenna 904 can serve to transmit radio frequency signals within a certain spectrum and/or at a certain frequency. As such, the wireless metal mesh antenna 904 can be any shape or size. Moreover, as described above, the wireless metal mesh antenna 904 (e.g., either with or without the metal mesh dummy fill 902) can feature a gradient mesh density such that it is less dense in the center than it is along its edges.

In one or more implementations, the metal mesh dummy fill 902 can serve to create or maintain a specified mesh density that allows the wireless metal mesh antenna 904 to operate as intended. For example, the metal mesh dummy fill 902 can feature a dummy size and an eliminate width. In at least one implementation, the dummy size can be less than half the wavelength of the metal mesh wireless antenna 904. In additional implementations, the dummy size can be less than a quarter of the wavelength of the metal mesh wireless antenna 904, or less than 0.1 of the wavelength of the metal mesh wireless antenna 904. Moreover, in one or more implementations, the eliminate width of the metal mesh dummy fill 902 can be minimized.

FIG. 10 illustrates a side view 1002 and a top view 1004 of an example implementation including a transparent conductor film 1006 (e.g., within an eye-tracking and antenna layer of a lens stack). In one or more implementations, the transparent conductor film 1006 may include both micro LEDs (e.g., such as the micro LEDs 1008a, 1008b) and one or more wireless metal mesh antennas 1010a, 1010b, and 1010c. For example, as shown in the side view 1002, the wireless metal mesh antenna 1010a may abut the transparent conductor film 1006 and be positioned in between the micro LEDs 1008a, 1008b. Moreover, as shown in the top view 1004, the additional wireless metal mesh antennas 1010b, 1010c may also be positioned between other pairs of micro LEDs and/or across a central aperture of the transparent conductor film 1006 inside the ring of micro LEDs. In this configuration, transparent metal mesh traces (e.g., such as the transparent metal mesh trace 1012) may connect the micro LEDs to an LED controller 1016. Additionally, the wireless metal mesh antennas 1010a-1010c may be connected to a radio frequency source 1014a.

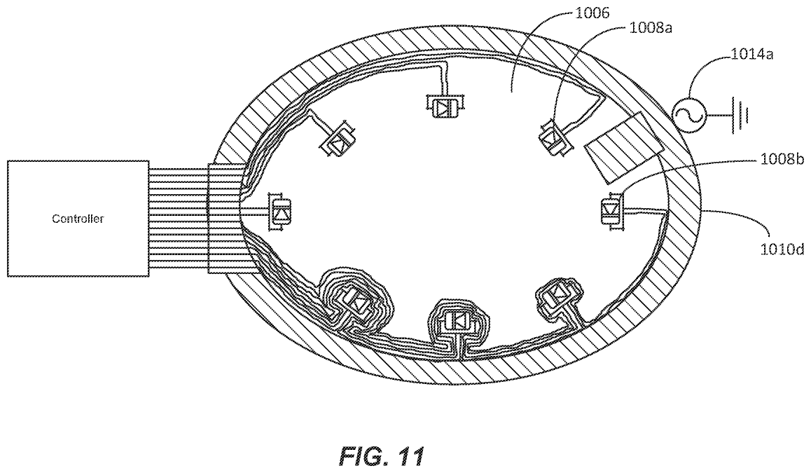

While FIG. 10 illustrates one configuration of micro LEDs and metal mesh wireless antennas, other configurations are possible. For example, as shown in FIG. 11, a wireless metal mesh antenna 1010d may be shaped and positioned in a ring that runs along a periphery of the transparent conductor film 1006 such that the one or more micro LEDs (e.g., such as the micro LEDs 1008a, 1008b) are positioned within the shape created by the wireless metal mesh antenna 1010d. In additional implementations, a wireless metal mesh antenna may feature any shape and may be placed at any location on the transparent conductor film 1006 adjacent to the one or more micro LEDs. Regardless of the shape and placement of the one or more wireless metal mesh antennas on the transparent conductor film 1006, the one or more wireless metal mesh antennas may be effectively invisible to the human eye.

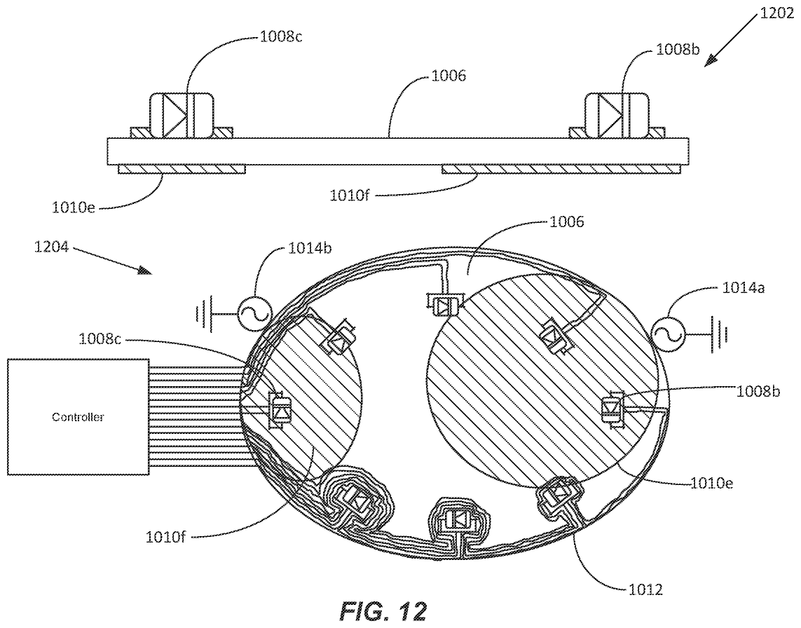

As shown in FIGS. 10 and 11, one or more implementations may include one or more wireless metal mesh antennas on the same side of the transparent conductor film 1006 as one or more micro LEDs and their associated transparent metal mesh traces. In additional implementations, other configurations are possible. For example, as shown in a side view 1202 in FIG. 12, an additional implementation can include one or more micro LEDs (e.g., such as the micro LEDs 1008b, 1008c) and their associated transparent metal mesh traces (e.g., such as the transparent metal mesh trace 1012) positioned to abut a first side of the transparent conductor film 1006 and one or more wireless metal mesh antennas (e.g., such as the wireless metal mesh antennas 1010e, 1010f) positioned to abut a second side of the transparent conductor film 1006.

Thus, as shown in a top view 1204 in FIG. 12, the wireless metal mesh antennas 1010e, 1010f may appear to overlap one or more of the micro LEDs (e.g., such as the micro LEDs 1008b, 1008c) because of the transparency of the transparent conductor film 1006. The implementation illustrated in FIG. 12 may also include an additional radio frequency source 1014b associated with the additional wireless metal mesh antenna 1010f. Moreover, in this implementation, the metal mesh of the wireless metal mesh antennas 1010e, 1010f may also feature a gradient mesh density such that the mesh density of the wireless metal mesh antennas 1010e, 1010f decreases toward the center of the of the transparent conductor film 1006 such that the transparency toward the center of the transparent conductor film 1006 increases.

In summary, the implementations described herein include transparent metal mesh in connection with various physical components of an eye-tracking system. As discussed above, the transparent metal mesh can allow for LED traces and/or wireless antennas to be implemented across portions of an optical aperture. Thus, by implementing transparent metal mesh in this way, the resulting head-mounted display device can feature increased functionality without sacrificing viewable area.

### Example Implementations

Example 1: An apparatus including a lens layer including a transparent lens, and an eye-tracking layer abutting the lens layer including one or more micro LEDs positioned on transparent conductor film, and transparent metal mesh traces positioned on the transparent conductor film and connecting the one or more micro LEDs to an LED controller adjacent to the transparent lens.

Example 2: The apparatus of Example 1, wherein the one or more micro LEDs are positioned within the eye-tracking layer to correspond with a periphery of the lens layer.

Example 3: The apparatus of Examples 1 and 2, wherein the transparent metal mesh traces connecting each LED to the LED controller are in a ladder configuration.

Example 4: The apparatus of any of Examples 1-3, wherein the apparatus further including a display layer including a waveguide for displaying virtual content, and the ladder configuration is randomized in the eye-tracking layer to prevent interference between the transparent metal mesh traces of the eye-tracking layer and the waveguide of the display layer of the apparatus.

Example 5: The apparatus of any of Examples 1-4, wherein the transparent metal mesh traces include an aperture ratio and mesh density that make the transparent metal mesh traces invisible to a user.

Example 6: The apparatus of any of Examples 1-5, wherein the transparent metal mesh traces comprise a width of less than 5 μm.

Example 7: The apparatus of any of Examples 1-6, wherein the transparent metal mesh traces comprise a thickness of less than 5 μm.

Example 8: An apparatus including a lens layer including a transparent lens, and an eye-tracking and antenna layer abutting the lens layer and including one or more micro LEDs positioned on a transparent conductor film, transparent metal mesh traces positioned on the transparent conductor film and connecting the one or more micro LEDs to an LED controller adjacent to the transparent lens, and one or more wireless metal mesh antenna elements adjacent to the one or more micro LEDs.

Example 9: The apparatus of Example 8, wherein the one or more micro LEDs are positioned along a periphery of the eye-tracking and antenna layer, and the one or more wireless metal mesh antenna elements comprise a wireless metal mesh antenna positioned central to the one or more micro LEDs.

Example 10: The apparatus of Examples 8 and 9, wherein the one or more micro LEDs are circularly positioned on the eye-tracking and antenna layer, and the one or more wireless metal mesh antenna elements include a ring-shaped wireless metal mesh antenna positioned outside the one or more micro LEDs on the eye-tracking and antenna layer.

Example 11: The apparatus of any of Examples 8-10, wherein the one or more wireless metal mesh antenna elements include a first wireless metal mesh antenna and a second wireless metal mesh antenna.

Example 12: The apparatus of any of Examples 8-11, wherein the transparent conductor film of the eye-tracking and antenna layer comprises a first side and a second side.

Example 13: The apparatus of any of Examples 8-12, wherein the one or more micro LEDS and the transparent metal mesh traces are positioned on the first side of the transparent conductor film and the first wireless metal mesh antenna and the second wireless metal mesh antenna are positioned on the second side of the transparent conductor film.

Example 14: A head-mounted display device including a pair of lenses within the head-mounted display device configured to be positioned in front of a user's eyes when the head-mounted display device is worn by the user, and an LED controller, wherein each of the pair of lenses includes a lens layer including a transparent lens, a display layer abutting the lens layer for displaying virtual content, and an eye-tracking layer abutting the display layer and including one or more micro LEDs positioned on a transparent conductor film, and transparent metal mesh traces positioned on the transparent conductor film and connecting the one or more micro LEDs to the LED controller.

Example 15: The head-mounted display device of Example 14, wherein the one or more micro LEDs are positioned within the eye-tracking layer to correspond with a periphery of the lens layer.

Example 16: The head-mounted display device of Examples 14 and 15, wherein the transparent metal mesh traces connecting each of the one or more micro LEDs to the LED controller are in a ladder configuration that is randomized in the eye-tracking layer to prevent interference between the transparent metal mesh traces of the eye-tracking layer and a waveguide of the display layer.

Example 17: The head-mounted display device of any of Examples 14-16, further including a first wireless metal mesh antenna positioned adjacent to the one or more micro LEDs on the eye-tracking layer.

Example 18: The head-mounted display device of any of Examples 14-17, further including a second wireless metal mesh antenna positioned adjacent to the first wireless metal mesh antenna on the eye-tracking layer.

Example 19: The head-mounted display device of any of Examples 14-18, wherein the transparent conductor film of the eye-tracking layer has a first side and a second side.

Example 20: The head-mounted display device of any of Examples 14-19, wherein the one or more micro LEDs and the transparent metal mesh traces are positioned on the first side of the transparent conductor film and the first wireless metal mesh antenna and the second wireless metal mesh antenna are positioned on the second side of the transparent conductor film.

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Embodiments of the present disclosure may include or be implemented in—conjunction with various types of artificial reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

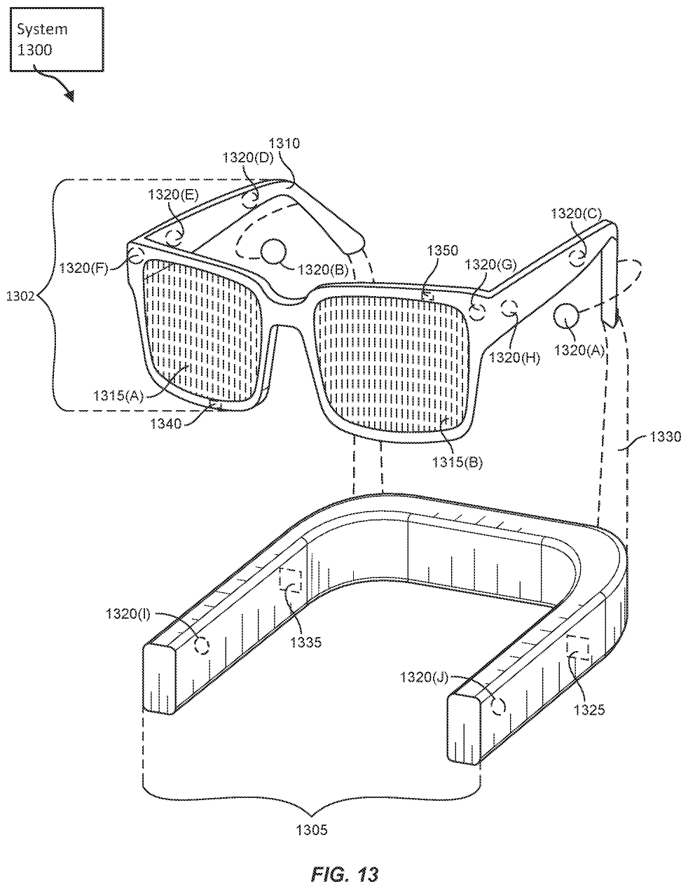

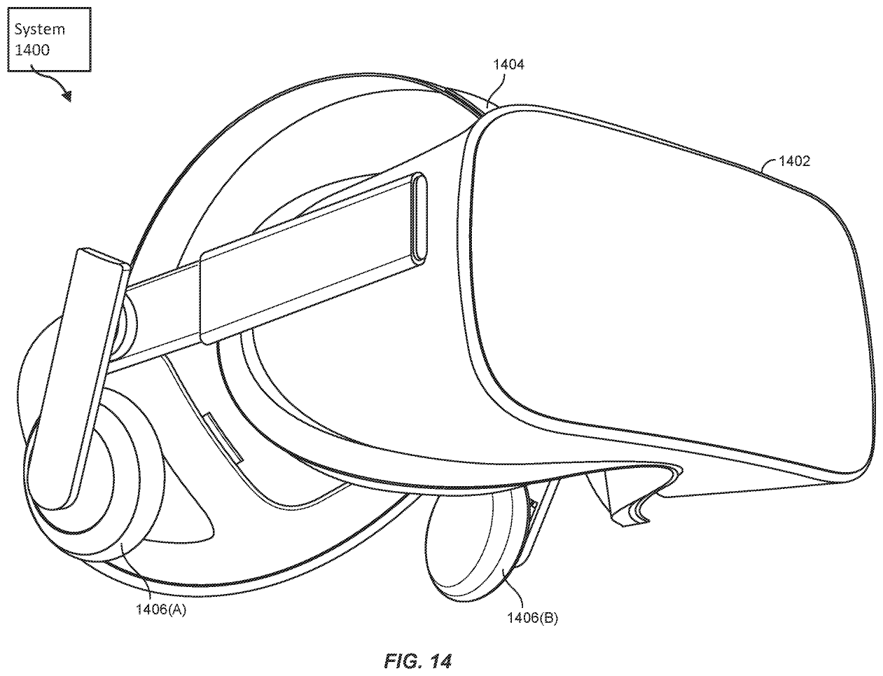

Artificial-reality systems may be implemented in a variety of different form factors and configurations. Some artificial reality systems may be designed to work without near-eye displays (NEDs). Other artificial reality systems may include an NED that also provides visibility into the real world (such as, e.g., augmented-reality system 1300 in FIG. 13) or that visually immerses a user in an artificial reality (such as, e.g., virtual-reality system 1400 in FIG. 14). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 13, augmented-reality system 1300 may include an eyewear device 1302 with a frame 1310 configured to hold a left display device 1315(A) and a right display device 1315(B) in front of a user's eyes. Display devices 1315(A) and 1315(B) may act together or independently to present an image or series of images to a user. While augmented-reality system 1300 includes two displays, embodiments of this disclosure may be implemented in augmented-reality systems with a single NED or more than two NEDs.

In some embodiments, augmented-reality system 1300 may include one or more sensors, such as sensor 1340. Sensor 1340 may generate measurement signals in response to motion of augmented-reality system 1300 and may be located on substantially any portion of frame 1310. Sensor 1340 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1300 may or may not include sensor 1340 or may include more than one sensor. In embodiments in which sensor 1340 includes an IMU, the IMU may generate calibration data based on measurement signals from sensor 1340. Examples of sensor 1340 may include, without limitation, accelerometers, gyroscopes, magnetometers, other suitable types of sensors that detect motion, sensors used for error correction of the IMU, or some combination thereof.

In some examples, augmented-reality system 1300 may also include a microphone array with a plurality of acoustic transducers 1320(A)-1320 J), referred to collectively as acoustic transducers 1320. Acoustic transducers 1320 may represent transducers that detect air pressure variations induced by sound waves. Each acoustic transducer 1320 may be configured to detect sound and convert the detected sound into an electronic format (e.g., an analog or digital format). The microphone array in FIG. 13 may include, for example, ten acoustic transducers: 1320(A) and 1320(B), which may be designed to be placed inside a corresponding ear of the user, acoustic transducers 1320(C), 1320(D), 1320(E), 1320(F),1320(G), and 1320(H), which may be positioned at various locations on frame 1310, and/or acoustic transducers 1320(I) and 1320(J), which may be positioned on a corresponding neckband 1305.

In some embodiments, one or more of acoustic transducers 1320(A)-(J) may be used as output transducers (e.g., speakers). For example, acoustic transducers 1320(A) and/or 1320(B) may be earbuds or any other suitable type of headphone or speaker.

The configuration of acoustic transducers 1320 of the microphone array may vary. While augmented-reality system 1300 is shown in FIG. 13 as having ten acoustic transducers 1320, the number of acoustic transducers 1320 may be greater or less than ten. In some embodiments, using higher numbers of acoustic transducers 1320 may increase the amount of audio information collected and/or the sensitivity and accuracy of the audio information. In contrast, using a lower number of acoustic transducers 1320 may decrease the computing power required by an associated controller 1350 to process the collected audio information. In addition, the position of each acoustic transducer 1320 of the microphone array may vary. For example, the position of an acoustic transducer 1320 may include a defined position on the user, a defined coordinate on frame 1310, an orientation associated with each acoustic transducer 1320, or some combination thereof.

Acoustic transducers 1320(A) and 1320(B) may be positioned on different parts of the user's ear, such as behind the pinna, behind the tragus, and/or within the auricle or fossa. Or there may be additional acoustic transducers 1320 on or surrounding the ear in addition to acoustic transducers 1320 inside the ear canal. Having an acoustic transducer 1320 positioned next to an ear canal of a user may enable the microphone array to collect information on how sounds arrive at the ear canal. By positioning at least two of acoustic transducers 1320 on either side of a user's head (e.g., as binaural microphones), augmented-reality system 1300 may simulate binaural hearing and capture a 3D stereo sound field around a user's head. In some embodiments, acoustic transducers 1320(A) and 120(B) may be connected to augmented-reality system 1300 via a wired connection 1330, and in other embodiments acoustic transducers 1320(A) and 120(B) may be connected to augmented-reality system 1300 via a wireless connection (e.g., a BLUETOOTH connection). In still other embodiments, acoustic transducers 1320(A) and 120(B) may not be used at all in conjunction with augmented-reality system 1300.

Acoustic transducers 1320 on frame 1310 may be positioned in a variety of different ways, including along the length of the temples, across the bridge, above or below display devices 115(A) and 115(B), or some combination thereof. Acoustic transducers 1320 may also be oriented such that the microphone array is able to detect sounds in a wide range of directions surrounding the user wearing the augmented-reality system 1300. In some embodiments, an optimization process may be performed during manufacturing of augmented-reality system 1300 to determine relative positioning of each acoustic transducer 1320 in the microphone array.

In some examples, augmented-reality system 1300 may include or be connected to an external device (e.g., a paired device), such as neckband 1305. Neckband 1305 generally represents any type or form of paired device. Thus, the following discussion of neckband 1305 may also apply to various other paired devices, such as charging cases, smart watches, smart phones, wrist bands, other wearable devices, hand-held controllers, tablet computers, laptop computers, other external compute devices, etc.

As shown, neckband 1305 may be coupled to eyewear device 1302 via one or more connectors. The connectors may be wired or wireless and may include electrical and/or non-electrical (e.g., structural) components. In some cases, eyewear device 1302 and neckband 1305 may operate independently without any wired or wireless connection between them. While FIG. 1 illustrates the components of eyewear device 1302 and neckband 1305 in example locations on eyewear device 1302 and neckband 1305, the components may be located elsewhere and/or distributed differently on eyewear device 1302 and/or neckband 1305. In some embodiments, the components of eyewear device 1302 and neckband 1305 may be located on one or more additional peripheral devices paired with eyewear device 1302, neckband 1305, or some combination thereof.

Pairing external devices, such as neckband 1305, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1300 may be provided by a paired device or shared between a paired device and an eyewear device, thus reducing the weight, heat profile, and form factor of the eyewear device overall while still retaining desired functionality. For example, neckband 1305 may allow components that would otherwise be included on an eyewear device to be included in neckband 1305 since users may tolerate a heavier weight load on their shoulders than they would tolerate on their heads. Neckband 1305 may also have a larger surface area over which to diffuse and disperse heat to the ambient environment. Thus, neckband 1305 may allow for greater battery and computation capacity than might otherwise have been possible on a stand-alone eyewear device. Since weight carried in neckband 1305 may be less invasive to a user than weight carried in eyewear device 1302, a user may tolerate wearing a lighter eyewear device and carrying or wearing the paired device for greater lengths of time than a user would tolerate wearing a heavy standalone eyewear device, thereby enabling users to more fully incorporate artificial reality environments into their day-to-day activities.

Neckband 1305 may be communicatively coupled with eyewear device 1302 and/or to other devices. These other devices may provide certain functions (e.g., tracking, localizing, depth mapping, processing, storage, etc.) to augmented-reality system 1300. In the embodiment of FIG. 1, neckband 1305 may include two acoustic transducers (e.g., 120(I) and 120(J)) that are part of the microphone array (or potentially form their own microphone subarray). Neckband 1305 may also include a controller 1325 and a power source 1335.

Acoustic transducers 1320(I) and 120(J) of neckband 1305 may be configured to detect sound and convert the detected sound into an electronic format (analog or digital). In the embodiment of FIG. 1, acoustic transducers 1320(I) and 120(J) may be positioned on neckband 1305, thereby increasing the distance between the neckband acoustic transducers 1320(I) and 120(J) and other acoustic transducers 1320 positioned on eyewear device 1302. In some cases, increasing the distance between acoustic transducers 1320 of the microphone array may improve the accuracy of beamforming performed via the microphone array. For example, if a sound is detected by acoustic transducers 1320(C) and 120(D) and the distance between acoustic transducers 1320(C) and 120(D) is greater than, e.g., the distance between acoustic transducers 1320(D) and 120(E), the determined source location of the detected sound may be more accurate than if the sound had been detected by acoustic transducers 1320(D) and 120(E).

Controller 1325 of neckband 1305 may process information generated by the sensors on neckband 1305 and/or augmented-reality system 1300. For example, controller 1325 may process information from the microphone array that describes sounds detected by the microphone array. For each detected sound, controller 1325 may perform a direction-of-arrival (DOA) estimation to estimate a direction from which the detected sound arrived at the microphone array. As the microphone array detects sounds, controller 1325 may populate an audio data set with the information. In embodiments in which augmented-reality system 1300 includes an inertial measurement unit, controller 1325 may compute all inertial and spatial calculations from the IMU located on eyewear device 1302. A connector may convey information between augmented-reality system 1300 and neckband 1305 and between augmented-reality system 1300 and controller 1325. The information may be in the form of optical data, electrical data, wireless data, or any other transmittable data form. Moving the processing of information generated by augmented-reality system 1300 to neckband 1305 may reduce weight and heat in eyewear device 1302, making it more comfortable to the user.

Power source 1335 in neckband 1305 may provide power to eyewear device 1302 and/or to neckband 1305. Power source 1335 may include, without limitation, lithium ion batteries, lithium-polymer batteries, primary lithium batteries, alkaline batteries, or any other form of power storage. In some cases, power source 1335 may be a wired power source. Including power source 1335 on neckband 1305 instead of on eyewear device 1302 may help better distribute the weight and heat generated by power source 1335.

As noted, some artificial reality systems may, instead of blending an artificial reality with actual reality, substantially replace one or more of a user's sensory perceptions of the real world with a virtual experience. One example of this type of system is a head-worn display system, such as virtual-reality system 1400 in FIG. 2, that mostly or completely covers a user's field of view. Virtual-reality system 1400 may include a front rigid body 1402 and a band 1404 shaped to fit around a user's head. Virtual-reality system 1400 may also include output audio transducers 1406(A) and 1406(B). Furthermore, while not shown in FIG. 14, front rigid body 1402 may include one or more electronic elements, including one or more electronic displays, one or more inertial measurement units (IMUs), one or more tracking emitters or detectors, and/or any other suitable device or system for creating an artificial-reality experience.

Artificial reality systems may include a variety of types of visual feedback mechanisms. For example, display devices in augmented-reality system 1300 and/or virtual-reality system 1400 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial reality systems may include a single display screen for both eyes or may provide a display screen for each eye, which may allow for additional flexibility for varifocal adjustments or for correcting a user's refractive error. Some of these artificial reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial reality systems described herein may include one or more projection systems. For example, display devices in augmented-reality system 1300 and/or virtual-reality system 1400 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial reality systems may also be configured with any other suitable type or form of image projection system, such as retinal projectors used in virtual retina displays.

The artificial reality systems described herein may also include various types of computer vision components and subsystems. For example, augmented-reality system 1300 and/or virtual-reality system 1400 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial reality system may process data from one or more of these sensors to identify a location of a user, to map the real world, to provide a user with context about real-world surroundings, and/or to perform a variety of other functions.

The artificial reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial reality systems described herein may also include tactile (i.e., haptic) feedback systems, which may be incorporated into headwear, gloves, bodysuits, handheld controllers, environmental devices (e.g., chairs, floor mats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial reality devices, within other artificial reality devices, and/or in conjunction with other artificial reality devices.

By providing haptic sensations, audible content, and/or visual content, artificial reality systems may create an entire virtual experience or enhance a user's real-world experience in a variety of contexts and environments. For instance, artificial reality systems may assist or extend a user's perception, memory, or cognition within a particular environment. Some systems may enhance a user's interactions with other people in the real world or may enable more immersive interactions with other people in a virtual world. Artificial reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial reality experience in one or more of these contexts and environments and/or in other contexts and environments.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus comprising:
a lens layer comprising a transparent lens; and
an eye-tracking layer abutting the lens layer and comprising:
one or more micro light emitting diodes (LEDs) positioned on a transparent conductor film; and
transparent metal mesh traces positioned on the transparent conductor film and connecting the one or more micro LEDs to an LED controller adjacent to the transparent lens.

2. The apparatus of claim 1, wherein the one or more micro LEDs are positioned within the eye-tracking layer to correspond with a periphery of the lens layer.

3. The apparatus of claim 1, wherein the transparent metal mesh traces connecting each LED to the LED controller are in a ladder configuration.

4. The apparatus of claim 3, wherein:
the apparatus further comprises a display layer comprising a waveguide for displaying virtual content; and
the ladder configuration is randomized in the eye-tracking layer to prevent interference between the transparent metal mesh traces of the eye-tracking layer and the waveguide of the display layer of the apparatus.

5. The apparatus of claim 1, wherein the transparent metal mesh traces comprise an aperture ratio and mesh density that make the transparent metal mesh traces invisible to a user.

6. The apparatus of claim 1, wherein the transparent metal mesh traces comprise a width of less than 5 μm.

7. The apparatus of claim 1, wherein the transparent metal mesh traces comprise a thickness of less than 5 μm.

8. An apparatus comprising:
a lens layer comprising a transparent lens; and
an eye-tracking and antenna layer abutting the lens layer and comprising:
one or more micro light emitting diodes (LEDs) positioned on a transparent conductor film;
transparent metal mesh traces positioned on the transparent conductor film and connecting the one or more micro LEDs to an LED controller adjacent to the transparent lens; and
one or more wireless metal mesh antenna elements adjacent to the one or more micro LEDs.

9. The apparatus of claim 8, wherein:
the one or more micro LEDs are positioned along a periphery of the eye-tracking and antenna layer; and
the one or more wireless metal mesh antenna elements comprise a wireless metal mesh antenna positioned central to the one or more micro LEDs.

10. The apparatus of claim 8, wherein:
the one or more micro LEDs are circularly positioned on the eye-tracking and antenna layer; and
the one or more wireless metal mesh antenna elements comprise a ring-shaped wireless metal mesh antenna positioned outside the one or more micro LEDs on the eye-tracking and antenna layer.

11. The apparatus of claim 8, wherein the one or more wireless metal mesh antenna elements comprise a first wireless metal mesh antenna and a second wireless metal mesh antenna.

12. The apparatus of claim 11, wherein the transparent conductor film of the eye-tracking and antenna layer comprises a first side and a second side.

13. The apparatus of claim 12, wherein the one or more micro LEDs and the transparent metal mesh traces are positioned on the first side of the transparent conductor film and the first wireless metal mesh antenna and the second wireless metal mesh antenna are positioned on the second side of the transparent conductor film.

14. A head-mounted display device comprising:
a pair of lenses within the head-mounted display device configured to be positioned in front of a user's eyes when the head-mounted display device is worn by the user; and
a light emitting diode (LED) controller;
wherein each of the pair of lenses comprises:
a lens layer comprising a transparent lens;
a display layer abutting the lens layer for displaying virtual content; and
an eye-tracking layer abutting the display layer and comprising:
one or more micro LEDs positioned on a transparent conductor film; and
transparent metal mesh traces positioned on the transparent conductor film and connecting the one or more micro LEDs to the LED controller.

15. The head-mounted display device of claim 14, wherein the one or more micro LEDs are positioned within the eye-tracking layer to correspond with a periphery of the lens layer.

16. The head-mounted display device of claim 14, wherein the transparent metal mesh traces connecting each of the one or more micro LEDs to the LED controller are in a ladder configuration that is randomized in the eye-tracking layer to prevent interference between the transparent metal mesh traces of the eye-tracking layer and a waveguide of the display layer.

17. The head-mounted display device of claim 16, further comprising a first wireless metal mesh antenna positioned adjacent to the one or more micro LEDs on the eye-tracking layer.

18. The head-mounted display device of claim 17, further comprising a second wireless metal mesh antenna positioned adjacent to the first wireless metal mesh antenna on the eye-tracking layer.

19. The head-mounted display device of claim 18, wherein the transparent conductor film of the eye-tracking layer has a first side and a second side.

20. The head-mounted display device of claim 19, wherein the one or more micro LEDs and the transparent metal mesh traces are positioned on the first side of the transparent conductor film and the first wireless metal mesh antenna and the second wireless metal mesh antenna are positioned on the second side of the transparent conductor film.
